(19) United States
(12) Patent Application Publication
(10) Pub. No.: US 2025/0038134 A1
(43) Pub. Date: Jan. 30, 2025

(54) SEMICONDUCTOR PACKAGE

(71) Applicant: SAMSUNG ELECTRONICS CO., LTD., SUWON-SI (KR)

(72) Inventors: Junbae KIM, Suwon-si (KR); Byounggug MIN, Suwon-si (KR); Yoochang SUNG, Suwon-si (KR)

(21) Appl. No.: 18/771,142

(22) Filed: Jul. 12, 2024

(30) Foreign Application Priority Data
Jul. 24, 2023 (KR) 10-2023-0096107

(51) Int. Cl. H01L 23/58; H01L 23/00; H01L 23/31; H01L 23/498; H01L 23/552; H01L 25/065; H10B 80/00

(52) U.S. Cl. CPC H01L 23/585; H01L 23/3107; H01L 23/49822; H01L 23/552; H01L 23/49816; H01L 24/16; H01L 24/32; H01L 24/48; H01L 24/73; H01L 25/0657; H01L 2224/16227; H01L 2224/32225; H01L 2224/48227; H01L 2224/73204; H01L 2224/73265; H01L 2225/0651; H10B 80/00

(57) ABSTRACT

A semiconductor package includes: a package substrate including upper pads, lower pads, and a first wiring layer electrically connecting first upper pads of the upper pads to first lower pads of the lower pads, respectively; a semiconductor chip disposed on the package substrate and electrically connected to the first upper pads; an encapsulant covering the semiconductor chip and at least a portion of the package substrate; a first conductive layer covering at least a portion of each of the encapsulant and the package substrate, wherein the first conductive layer is configured to apply a first voltage; a dielectric layer stacked on the first conductive layer; and a second conductive layer stacked on the dielectric layer, wherein the second conductive layer is configured to apply a second voltage.

### CROSS-REFERENCE TO RELATED APPLICATION

This application claims priority under 35 U.S.C. § 119 to Korean Patent Application No. 10-2023-0096107 filed on Jul. 24, 2023, in the Korean Intellectual Property Office, the disclosure of which is incorporated by reference herein in its entirety.

### TECHNICAL FIELD

Example embodiments of the present inventive concept relate to a semiconductor package.

### DISCUSSION OF THE RELATED ART

As electronic devices decrease in weight and increase performance, demand for further development of packages that can protect semiconductor chips from electromagnetic interference (EMI) increases. A semiconductor package with an EMI shielding structure that is introduced to the outside of the semiconductor package is currently under development.

### SUMMARY

According to an example embodiment of the present inventive concept, a semiconductor package includes: a package substrate including upper pads, lower pads, and a first wiring layer electrically connecting first upper pads of the upper pads to first lower pads of the lower pads, respectively; a semiconductor chip disposed on the package substrate and electrically connected to the first upper pads; an encapsulant covering the semiconductor chip and at least a portion of the package substrate; a first conductive layer covering at least a portion of each of the encapsulant and the package substrate, wherein the first conductive layer is configured to apply a first voltage; a dielectric layer stacked on the first conductive layer; and a second conductive layer stacked on the dielectric layer, wherein the second conductive layer is configured to apply a second voltage.

According to an example embodiment of the present inventive concept, a semiconductor package includes: a package body including a package substrate, which includes a first wiring layer and a second wiring layer, a semiconductor chip, which is disposed on the package substrate and is electrically connected to the first wiring layer, and an encapsulant covering the semiconductor chip and at least a portion of the package substrate; a condenser structure including a first conductive layer, which is covers a side surface and an upper surface of the package body, a dielectric layer, which is disposed on the first conductive layer, and a second conductive layer, which is disposed on the dielectric layer; a conductive structure contacting with the second conductive layer of the condenser structure; a base substrate including first connection wiring, which is disposed below the package body and the conductive structure and is electrically connected to the first wiring layer, a second connection wiring electrically connected to the second wiring layer, and a third connection wiring electrically connected to the conductive structure; and first to third connection bumps disposed below the base substrate and electrically connected to the first to third connection wires, respectively.

According to an example embodiment of the present inventive concept, a semiconductor package includes: a package substrate including first and second upper pads, first, second and third lower pads, a first wiring layer, which electrically connects the first upper pads to the first lower pads, a second wiring layer, which electrically connects the second upper pads to the second lower pads, and a third wiring layer, which is electrically connected to the third lower pads; a semiconductor chip disposed on the package substrate and electrically connected to the first upper pads; an encapsulant covering the semiconductor chip and a first portion of an upper surface of the package substrate; a first conductive layer covering a side surface and an upper surface of the encapsulant, wherein the first conductive layer is connected to the second upper pads that are disposed in a second portion of the upper surface of the package substrate; a dielectric layer extending along a surface of the first conductive layer and the second portion of the upper surface of the package substrate; and a second conductive layer extending along a surface of the dielectric layer and a side surface of the package substrate, wherein the second conductive layer is connected to the third wiring layer at the side surface of the package substrate.

### BRIEF DESCRIPTION OF DRAWINGS

The above and other aspects of the present inventive concept will become more apparent by describing in detail example embodiments thereof, with reference to the accompanying drawings, in which:

FIG. 1 is a cross-sectional view illustrating a semiconductor package according to an example embodiment of the present inventive concept;

FIG. 2 is a top view of the semiconductor package of FIG. 1 when viewed from above;

FIG. 3 is a cross-sectional view illustrating a semiconductor package according to an example embodiment of the present inventive concept;

FIG. 4 is a cross-sectional view illustrating a semiconductor package according to an example embodiment of the present inventive concept;

FIG. 5 is a cross-sectional view illustrating a semiconductor package according to an example embodiment of the present inventive concept;

FIGS. 6, 7, 8, 9, 10, 11, 12, 13, 14, 15 and 16 are cross-sectional views schematically illustrating a manufacturing process of a semiconductor package according to an example embodiment of the present inventive concept;

FIG. 17 is a cross-sectional view illustrating a semiconductor package according to an example embodiment of the present inventive concept;

FIG. 18 is a top view of the semiconductor package of FIG. 17 when viewed from above;

FIGS. 19, 20, 21, 22, 23, 24, 25, 26 and 27 are cross-sectional views schematically illustrating a manufacturing process of a semiconductor package according to an example embodiment of the present inventive concept;

FIG. 28 is a cross-sectional view illustrating a semiconductor package according to an example embodiment of the present inventive concept;

FIGS. 29, 30, 31, 32, 33, 34, 35, 36, 37, and 38 are cross-sectional views illustrating a semiconductor package according to an example embodiment of the present inventive concept;

FIG. 39 is a cross-sectional view illustrating a semiconductor package according to an example embodiment of the present inventive concept; and

FIGS. 40, 41, 42, 43, 44, 45, 46, and 47 are cross-sectional views illustrating a semiconductor package according to an example embodiment of the present inventive concept.

### DETAILED DESCRIPTION OF THE EMBODIMENTS

Hereinafter, example embodiments of the present inventive concept will be described with reference to the accompanying drawings. It will be understood that spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, in the example, terms “below” and “beneath” may encompass both an orientation of above, below and beneath. The device may be otherwise oriented (e.g., rotated 90 degrees or at other orientations) and the spatially relative descriptors used herein may be interpreted accordingly.

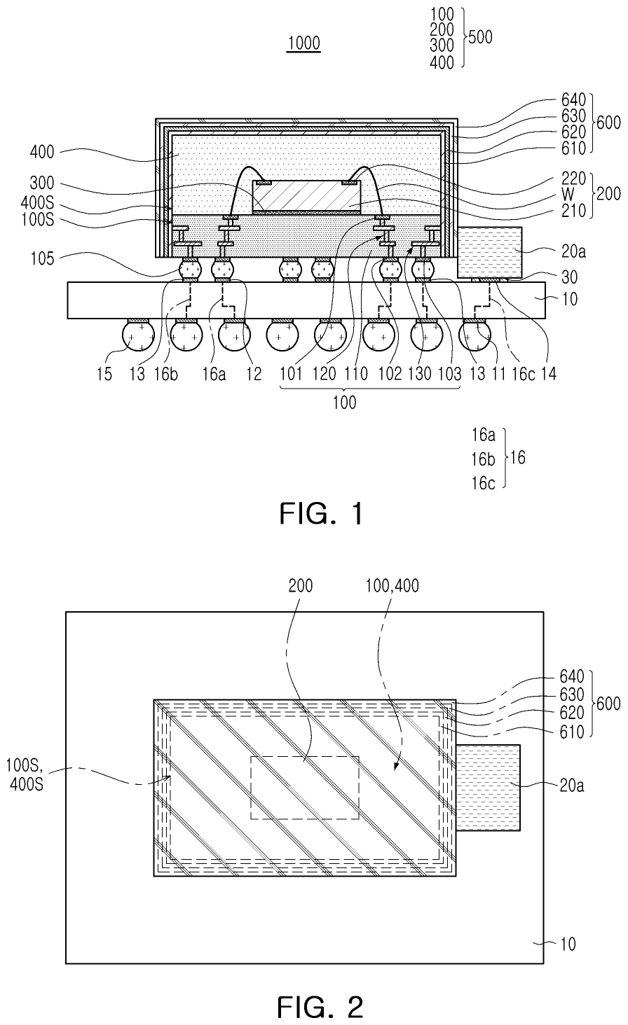

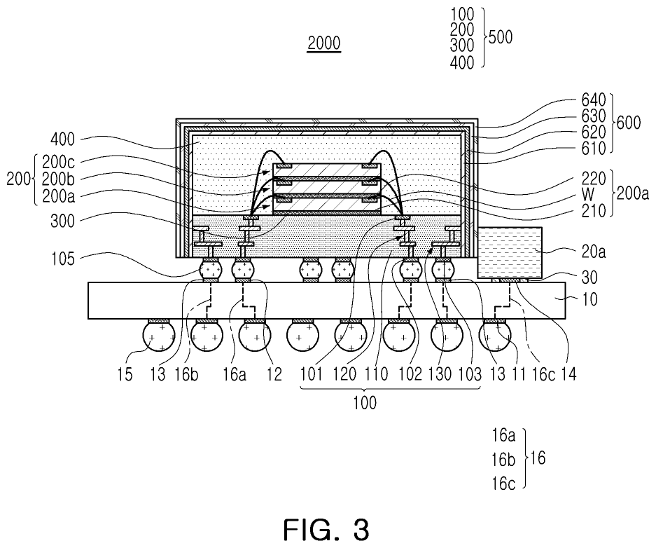

FIG. 1 is a cross-sectional view illustrating a semiconductor package 1000 according to an example embodiment of the present inventive concept. FIG. 2 is a top view of the semiconductor package 1000 of FIG. 1 when viewed from above. FIG. 3 is a cross-sectional view illustrating a semiconductor package 2000 according to an example embodiment of the present inventive concept.

Referring to FIGS. 1 to 3, semiconductor packages 1000 and 2000 according to an example embodiment of the present inventive concept may include a base substrate 10, a conductive structure 20a, an adhesive material 30, a package body 500, and a condenser structure 600. The package body 500 may include a package substrate 100, a semiconductor chip 200, an adhesive film 300, and an encapsulant 400. According to an example embodiment of the present inventive concept, the package body 500 may include a package substrate 100, a semiconductor chip 200 in which a plurality of semiconductor chips 200a, 200b and 200c are stacked on each other, an adhesive film 300, and an encapsulant 400 (see FIG. 3).

According to an example embodiment of the present inventive concept, in a process of depositing a plurality of conductive layers including layers for shielding on a side surface and an upper surface of the package body 500, a process of depositing a dielectric layer may be further advanced, and an electrical connection relationship may be added to a portion of the plurality of conductive layers, thereby providing the semiconductor packages 1000 and 2000 that are using the dielectric layer as a portion of a capacitor.

Hereinafter, each component will be described in detail with reference to the drawings.

The semiconductor chip 200 may be comprised of memory chips or memory elements configured to store or output data based on address commands and control commands received from the package substrate 100. For example, the semiconductor chip 200 (or each of semiconductor chips 200 in which a plurality of semiconductor chips 200a, 200b and 200c are sequentially stacked on each other) may include logic chips (or ‘logic circuits’) including a central processor (CPU), a graphics processor (GPU), a field programmable gate array (FPGA), an application processor (AP), a digital signal processor, an encryption processor, microprocessors, microcontrollers, an analog-to-digital converter, application-specific IC (ASIC), or the like, and memory chips (or ‘memory circuits’) including a volatile memory such as dynamic RAM (DRAM) and static RAM (SRAM) and a non-volatile memory such as a phase change RAM (PRAM), a magnetic RAM (MRAM), a resistive RAM (RRAM), a flash memory, or the like. The semiconductor chip 200 may be attached to an upper surface of the package substrate 100 by using an adhesive film 300 (e.g., a die attach film).

The semiconductor chip 200 may be electrically connected to the package substrate 100 through a conductive wire W that is connected to conductive pads 220 of the semiconductor chip 200 and upper pads 101 of the package substrate 100.

The package substrate 100 may include an insulating layer 110, upper pads 101, lower pads 102 and 103, and a plurality of wiring layers 120 and 130. Accordingly, the package substrate 100 may transmit signals from the semiconductor chip 200 that is disposed on the package substrate 100 to the outside, and may also transmit signals and power from the outside to the semiconductor chip 200.

The insulating layer 110 may include an insulating resin. The insulating resin may include, for example, a thermosetting resin such as an epoxy resin, a thermoplastic resin such as polyimide, or resins in which inorganic fillers are impregnated in these resins, for example, prepreg, Ajinomoto Build-up Film (ABF), FR-4, and Bismaleimide-Triazine (BT). For example, the insulating layer 110 may include a photosensitive resin such as a photo-imaging dielectric (PID). The insulating layer 110 may include a plurality of insulating layers stacked in a vertical direction. For example, depending on the process, a boundary between a plurality of insulating layers may be unclear; however, the present inventive concept is not limited thereto.

The upper pad 101 may be disposed in an upper portion of the package substrate 100. An upper surface of the upper pad 101 may be exposed at an upper surface of the package substrate 101. The upper pad 101 may include, for example, at least one of aluminum (Al), copper (Cu), nickel (Ni), tungsten (W), platinum (Pt), and/or gold (Au). The lower pads 102 and 103 may be disposed in a lower portion of the package substrate 100 and may include a material similar to that of the upper pad 101. However, the materials of the upper pad 101 and the lower pads 102 and 103 are not limited to the materials described above.

The plurality of wiring layers 120 and 130 may include, for example, a multilayer structure including a wiring pattern and a via formed of aluminum (Al), gold (Au), cobalt (Co), copper (Cu), nickel (Ni), lead (Pb), tantalum (Ta), tellurium (Te), titanium (Ti), tungsten (W) or combinations thereof. The plurality of wiring layers 120 and 130 may be connected to the lower pads 102 and 103 in a lower end thereof, and a first wiring layer 120 of the plurality of wiring layers may be connected to the upper pad 101, which is exposed at the upper surface of the package substrate 100, in an upper end thereof. The first wiring layer 120 of the plurality of wiring layers may be electrically connected to the semiconductor chip 200 through the upper pads 101 of the package substrate 100. A second wiring layer 130 of the plurality of wiring layers may be in contact with and electrically connected to at least one layer of the condenser structure 600. The second wiring layer 130 may be electrically connected to a first conductive layer 610 of the condenser structure 600 by coming into contact with a side surface of the first conductive layer 610 on a side surface thereof. Each of the first wiring layer 120 and the second wiring layer 130 may be electrically insulated from each other.

The encapsulant 400 may seal the semiconductor chip 200 on the package substrate 100. Referring to FIG. 2, a horizontal area of the encapsulant 400 may be the same or substantially the same as a horizontal area of the package substrate 100. For example, a side surface 400S of the encapsulant may be coplanar or substantially coplanar with a side surface 100S of the package substrate. However, according to an embodiment of the present inventive concept, a horizontal area of the encapsulant 400 may be less than a horizontal area of the package substrate 100. For example, the side surface 100S of the package substrate may be disposed outside the side surface 400S of the encapsulant. The encapsulant 400 may be formed of an insulating material such as Epoxy Mold Compound (EMC), but the material of the encapsulant 400 is not particularly limited.

The condenser structure 600 may include a first conductive layer 610, a dielectric layer 620, and a second conductive layer 640 stacked on a side surface and an upper surface of the package body 500. The condenser structure 600 may further include a third conductive layer 630 that is disposed between the dielectric layer 620 and the second conductive layer 640.

The first conductive layer 610 may be disposed to cover a side surface and an upper surface of the package body 500. The electrical conductivity of the first conductive layer 610 may be less than that of the third conductive layer 630 that is disposed between the dielectric layer 620 and the second conductive layer 640. The first conductive layer 610 may be in contact with the second wiring layer 130 of the plurality of wiring layers of the package substrate 100, and may be disposed on the side surface 100S of the package substrate. The second wiring layer 130 may provide an electrical connection path to the first conductive layer 610, and a first voltage V1 may be applied to the first conductive layer 610 through the second wiring layer 130.

The dielectric layer 620 may be disposed on the first conductive layer 610. The dielectric layer 620 may include a dielectric material that electrically insulates layers that are disposed on both sides of the dielectric layer 620. The dielectric layer 620 may include a dielectric material having a dielectric constant of about 20 [V/m] or more, for example, about 20 to about 30, or about 20 to about 25. The dielectric layer 620 may include at least one of, for example, zirconium oxide (ZrO₂) and/or hafnium oxide (HfO₂), but the present inventive concept is not limited thereto.

The second conductive layer 640 may be disposed on the dielectric layer 620. The second conductive layer 640 may be a layer for preventing the third conductive layer 630, which is disposed between the dielectric layer 620 and the second conductive layer 640, from being oxidized, but the present inventive concept is not limited thereto. Accordingly, the electrical conductivity of the second conductive layer 640 may be less than that of the third conductive layer 630. The electrical conductivity of the second conductive layer 640 may be the same as that of the first conductive layer 610, and a material of the second conductive layer 640 may be the same as that of the first conductive layer 610. The conductive structure 20a may be disposed to be connected with an external surface of the second conductive layer 640. For example, the conductive structure 20a may be disposed to be in contact with an external surface of the second conductive layer 640. The conductive structure 20a may provide an electrical connection path to the second conductive layer 640, and a second voltage V2 may be applied to the second conductive layer 640 through the conductive structure 20a.

The first conductive layer 610 and the second conductive layer 640 may include a conductive material. The first conductive layer 610 may include, for example, a metal including tin (Sn), iron (Fe), nickel (Ni), or alloys thereof. The second conductive layer 640 may include a material similar to that of the first conductive layer 610. However, the materials of the first conductive layer 610 and the second conductive layer 640 are not limited to the materials described above. The first conductive layer 610 and the second conductive layer 640 may include, for example, steel used stainless (SUS).

The first voltage V1 applied to the first conductive layer 610 may be greater than the second voltage V2 applied to the second conductive layer 640. The first voltage V1 may be, for example, Vdd, and the second voltage V2 may be, for example, Vss.

The third conductive layer 630 may be disposed between the dielectric layer 620 and the second conductive layer 640. The third conductive layer 630 may prevent the semiconductor packages 1000 and 2000 from being subject to electromagnetic interference (EMI) from the outside, but the present inventive concept is not limited thereto. The electrical conductivity of the third conductive layer 630 may be greater than the electrical conductivity of each of the first conductive layer 610 and the second conductive layer 630. The third conductive layer 630 may include a conductive material. The third conductive layer 630 may include a metal including, for example, gold (Au), silver (Ag), copper (Cu), or alloys thereof, but the present inventive concept is not limited thereto.

Each of a plurality of layers 610, 620, 630 and 640 constituting the condenser structure 600 may have a substantially uniform thickness along a circumference of the package body 500, but the present inventive concept is not limited thereto. For example, a thickness of the plurality of layers 610, 620, 630 and 640 that are stacked on the side surface of the package body 500 may be thinner than a thickness of the plurality of layers 610, 620, 630 and 640 that are stacked on the upper surface of the package body 500. The dielectric layer 620 disposed on the upper surface of the package body 500 may have a thickness greater than that of at least one of the first or second conductive layers 610 and 640 that are disposed on the upper surface of the package body 500. For example, the dielectric layer 620 may have a thickness of about 5 μm or less, for example, about 10 nm to about 5 μm, or about 50 nm to about 2 μm, or about 100 nm to about 1 μm. The first and second conductive layers 610 and 640 may have a thickness of about 1 μm or less, for example, about 100 nm to about 1 μm, or about 200 nm to about 0.5 μm.

The base substrate 10 may be disposed below the package body 500. The base substrate may include a rear pad 11, a front pad 12, 13, and 14, and connection wires 16a, 16b and 16c.

The base substrate 10 may be a substrate on which an electronic circuit is formed by fixing electronic components such as a resistor, a condenser and an integrated circuit to a surface and connecting the components with wires, but the present inventive concept is limited thereto.

The rear pad 11 may be disposed on a lower surface of the base substrate 10. The rear pads 11 may include, for example, at least one of aluminum (Al), copper (Cu), nickel (Ni), tungsten (W), platinum (Pt), and/or gold (Au). The front pads 12, 13 and 14 may be disposed on a front surface of the base substrate 10. At least some of the front pads 12, 13 and 14 may be disposed on the same line as at least some of the lower pads 102 and 103 of the package substrate 100. At least some of the front pads may be connection pads 14 that are disposed below the conductive structure 20a to provide an electrical connection path. The front pads 12, 13 and 14 may include a similar material to the rear pad 11. However, the materials of the rear pad 11 and the front pads 12, 13 and 14 are not limited to the materials described above.

The base substrate 10 may include a plurality of connection wires 16 for electrically connecting each of the lower pads 102 and 103 of the package substrate 100 and the conductive structure 20a to the rear pads 11. Among the plurality of connection wires 16, a first connection wiring 16a, a second connection wiring 16b, and a third connection wiring 16c. The first connection wiring 16a may electrically connect some of the first lower pads 102, which are in contact with the first wiring layer 120, with the rear pads 11. The second connection wiring 16b may electrically connect at least some of the second lower pads 103, which are in contact with the second wiring layer 130, with the rear pads, and the third connection wiring 16c may be electrically connected to the conductive structure 20a. The semiconductor chip 200 may be electrically connected to the first connection wiring 16a and the first wiring layer 120, and the first conductive layer 610 may be electrically connected to the second connection wiring 16b and the second wiring layer 130. The second conductive layer 620 may be electrically connected to the third connection wiring 16c and the conductive structure 20a. The connection wires 16a, 16b and 16c may be formed as a multilayer structure including a wiring pattern and a via made of, for example, aluminum (Al), gold (Au), cobalt (Co), copper (Cu), nickel (Ni), lead (Pb), tantalum (Ta), tellurium (Te), titanium (Ti), tungsten (W), or combinations thereof.

A plurality of bump structures 105 may be disposed between the package body 500 and the base substrate 10. The bump structures 105 may electrically connect the lower pads 102 and 103 of the package substrate 100 and at least some of the front pads 12, 13 and 14 of the base substrate 10 to each other. The bump structures 105 may include, for example, tin (Sn), indium (In), bismuth (Bi), antimony (Sb), copper (Cu), silver (Ag), zinc (Zn), and lead (Pb) and/or alloys thereof. The alloy may include, for example, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, and Sn—Bi—Zn. According to an example embodiment of the present inventive concept, the bump structures 105 may have a combination of a metal pillar and a solder ball. The base substrate 10 may have a width greater than a width of the package substrate 100 in a horizontal direction (parallel to the upper surface) (e.g., X-direction and/or Y-direction). At least some of the bump structures 105 and at least some of the lower pads 102 and 103 may be disposed in a position in which they do not overlap the semiconductor chip 200 in a vertical direction (Z-direction).

A plurality of connection bumps 15 including a first connection bump, a second connection bump, and a third connection bump may be additionally disposed below the base substrate 10. The connection bumps 15 may be disposed to come into contact with the rear pads 11 that are disposed on a lower surface of the base substrate 10. The connection bumps 15 may include a material similar to the bump structures 105 that are disposed between the package body 500 and the base substrate 10. However, the materials of the connection bumps 15 and bump structures 105 are not limited to the materials described above.

A conductive structure 20a may be disposed on the base substrate 10. A conductive structure 20a may be disposed above the base substrate 10. The conductive structure 20a may include a conductive material such as iron (Fe), nickel (Ni), tin (Sn), and molybdenum (Mo), but the present inventive concept is not limited thereto. The conductive structure 20a may be disposed to be in contact with at least one layer of the condenser structure 600 and may be in contact with the second conductive layer 640 of the condenser structure. In this case, the second conductive layer 640 may receive an electrical connection path by coming into contact with the conductive structure 20a.

An adhesive layer 30 may be disposed between the conductive structure 20a and the base substrate 10. The adhesive layer 30 may include an adhesive polymer material such as a polymer binder resin, an epoxy resin, a phenol-type epoxy curing agent, a curing catalyst, or a silane coupling agent, and may be in the form of a paste or film, but the present inventive concept is not limited thereto. The adhesive layer 30 may be disposed to at least partially surround the connection pad 14 that is disposed between the conductive structure 20a and the base substrate 10. A thickness of the connection pad 14 may be substantially identical to a thickness of the adhesive layer 30.

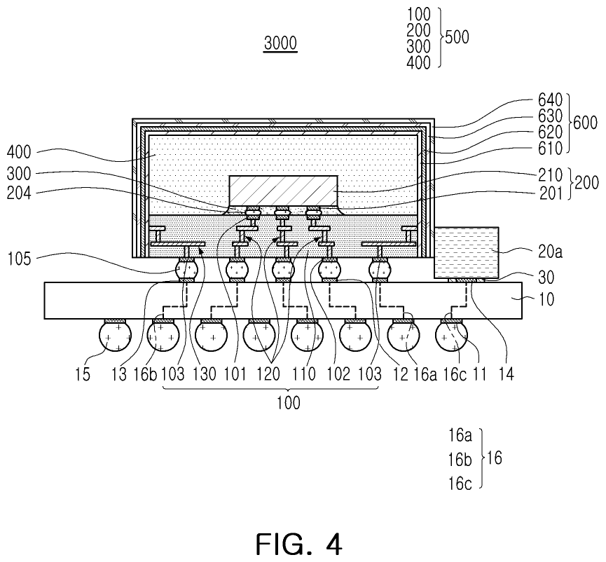

FIG. 4 is a cross-sectional view illustrating a semiconductor package 3000 according to an example embodiment of the present inventive concept.

Referring to FIG. 4, the semiconductor package 3000 according to an example embodiment of the present inventive concept may have the characteristics that are identical or similar to those described with reference to FIGS. 1 to 3, except that the semiconductor chip 200 that is disposed on the package substrate 100 is in the form of a flip chip. For example, the semiconductor chip 200 may be disposed on an upper portion of a package substrate 100 by using an adhesive film 300 (or ‘an underfill layer’).

The adhesive film 300 may be an underfill layer that at least partially surrounds the bump structures 204 that are disposed between the package substrate 100 and the semiconductor chip 200 among the bump structures 204, and fixes the semiconductor chip 200 to the package substrate 100. The underfill layer may include an insulating material. The underfill layer may be formed using a CUF process, but the present inventive concept is not limited thereto.

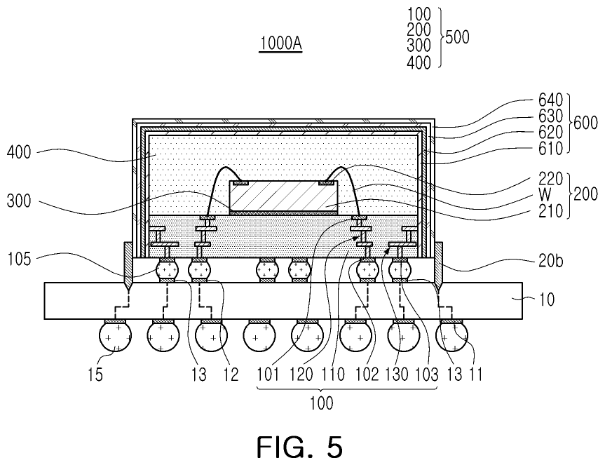

FIG. 5 is a cross-sectional view illustrating a semiconductor package 1000A according to an example embodiment of the present inventive concept.

Referring to FIG. 5, the semiconductor package 1000A according to an example embodiment of the present inventive concept may have characteristics that are identical or similar to those described with reference to FIGS. 1 to 3, except that a portion of the conductive structure 20, which is disposed on an upper portion of the base substrate 10 and is in contact with an external surface of the condenser structure 600, is mounted in a manner in which it is inserted into a concave portion or groove of the base substrate 10. For example, a portion of a conductive structure 20b may be inserted into an insertion portion (e.g., a socket) disposed in an upper portion of the base substrate 10, and may be electrically connected to some of a plurality of connection wirings of the base substrate 10.

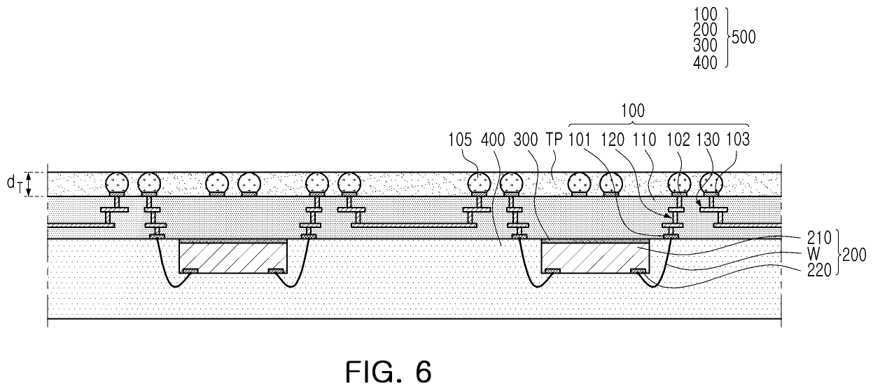

FIGS. 6 to 16 are cross-sectional views schematically illustrating a manufacturing process of a semiconductor package 1000 according to an example embodiment of the present inventive concept.

Referring to FIG. 6, ‘a first package assembly’ may be provided in face-up form. In the first package assembly, a package substrate 100 extending horizontally may be provided, a plurality of semiconductor chips 200 attached to one surface of a package substrate 100 with an insulating film 300 may be disposed horizontally, and an encapsulant 400 at least partially surrounding the plurality of semiconductor chips 200 may be disposed on one surface of the package substrate 100. In addition, a plurality of connection bumps 105 may be disposed on another surface of the package substrate 100. According to an example embodiment of the present inventive concept, a first package assembly may be provided in a form in which the semiconductor chip 200 in which a plurality of semiconductor chips 200a, 200b and 200c are vertically stacked is attached to one surface of the package substrate 100 with an insulating film 300 (see FIG. 3). According to an example embodiment of the present inventive concept, a first package assembly may be provided in a form in which the semiconductor chip 200 is attached to the package substrate 100 by a plurality of bump structures 204.

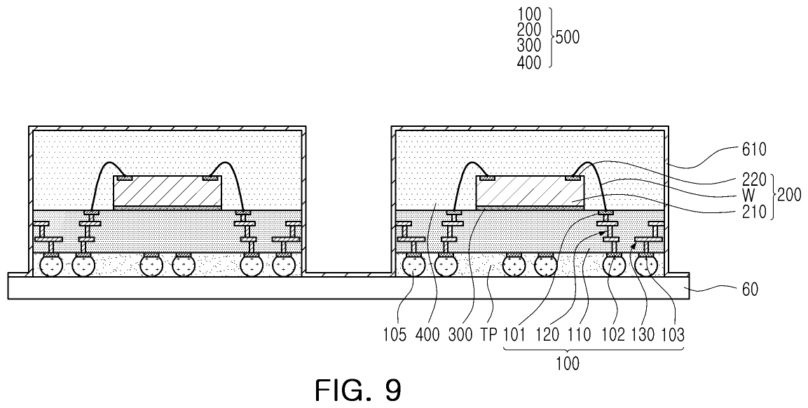

Referring to FIG. 6, for a deposition process according to FIG. 9, a tape TP may be attached to cover one side surface of the package substrate 100 and may at least partially surround the plurality of connection bumps 105. The tape TP may include a UV curing polymer. The tape TP may include a photosensitive polymer such as polyester-acrylate resin or an epoxy-acrylate resin, but the present inventive concept is not limited thereto. The tape TP may have a predetermined thickness dr.

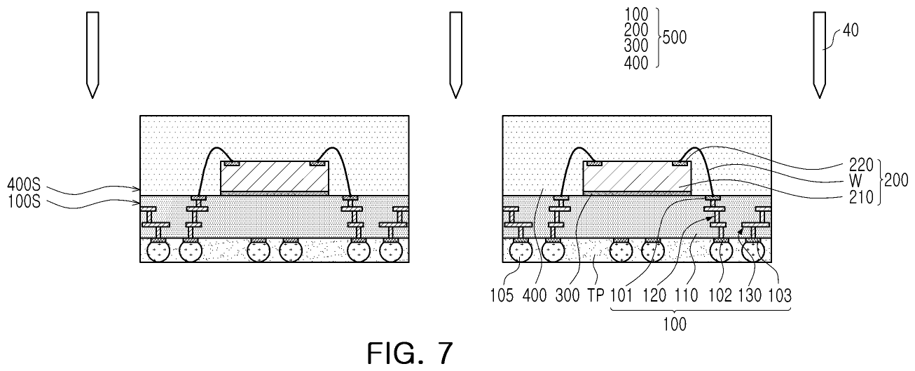

Referring to FIG. 7, a plurality of package bodies 500 may be provided through a process of sawing a first package assembly in a direction, substantially perpendicular to an upper surface thereof, by using a cutter 40. Through the sawing process, a portion of a wiring layer 130 of the package substrate 100 may be exposed to a side surface 100S of the package substrate 100.

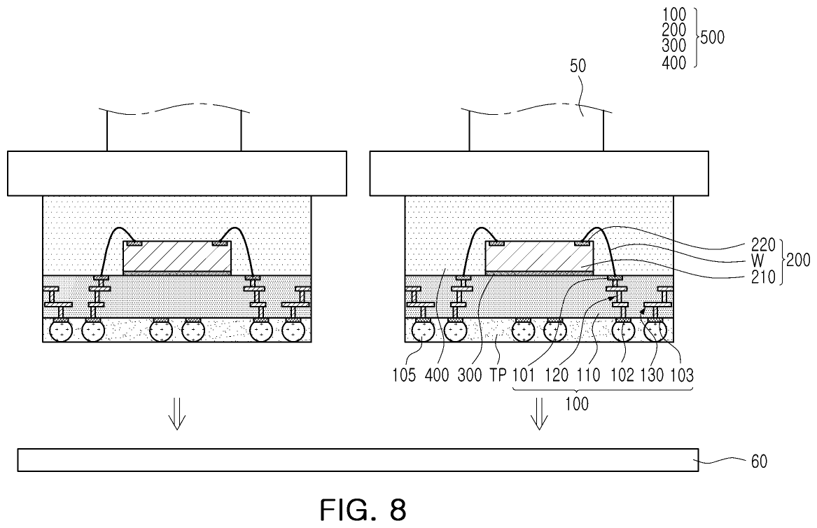

Referring to FIG. 8, each of the plurality of package bodies 500 may be picked through vacuum adsorption force (e.g., a suction) that is applied through the bonding head 50 and may be placed on a support substrate 60. The support substrate 60 may include an insulating polymer material such as polyimide, and may be provided in the form of a film.

Referring to FIGS. 9 to 12, a plurality of layers 610, 620, 630 and 640 forming a condenser structure 600 may be deposited sequentially along an upper surface and a side surface of a package body 500, a side surface of the tape TP, and an upper surface of the support substrate 60. Depositions may include physical vapor deposition (PVD), chemical vapor deposition (CVD), and atomic layer deposition (ALD), but the present inventive concept is not limited thereto. The deposition may be performed by a sputtering process even in the physical vapor deposition (PVD), but the present inventive concept is not limited thereto.

Before depositing the plurality of layers 610, 620, 630 and 640, by irradiating UV or the like, the tape TP including a photosensitive polymer may be hardened and adhesive strength thereof may be weakened.

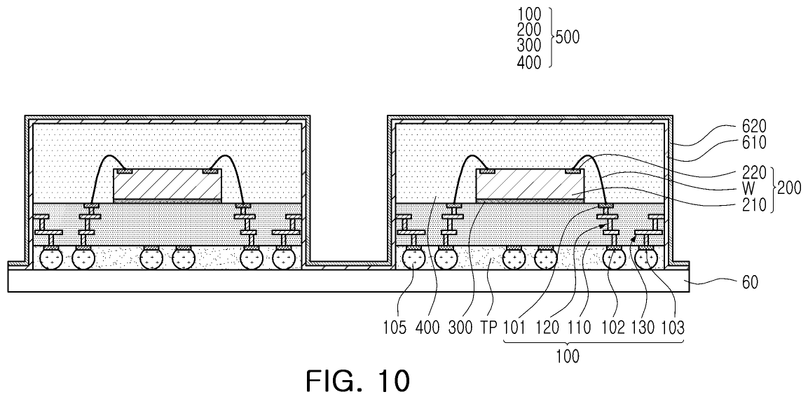

As illustrated in FIG. 9, a first conductive layer 610 may be deposited to cover the upper surface and the side surface of the package body 500, the side surface of the tape TP, and the upper surface of the support substrate 60. As illustrated in FIG. 10, a dielectric layer 620 may be deposited to cover a surface of the first conductive layer 610.

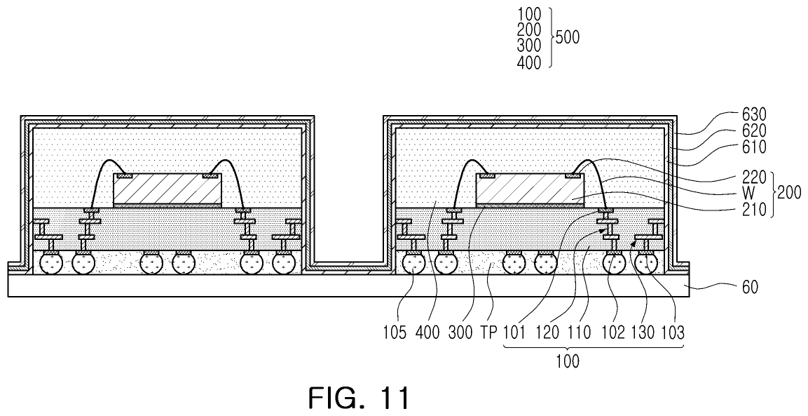

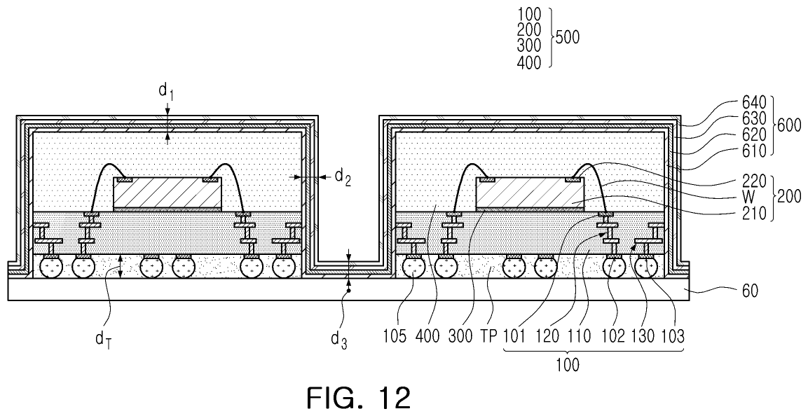

As illustrated in FIGS. 11 and 12, a third conductive layer 630 may be deposited to cover a surface of a dielectric layer 620, and a second conductive layer 640 may be deposited to cover a surface of the third conductive layer 630. Accordingly, the first conductive layer 610, the dielectric layer 620, and the second conductive layer 640 may be stacked, but a structure may be formed in which the third conductive layer 630 is disposed between the dielectric layer 620 and the second conductive layer 640. A thickness d₁ of a condenser structure 600 that covers the upper surface of the package body 500 may be substantially identical to a thickness d₃ of a condenser structure 600 that covers the upper surface of the support substrate 60. The thickness d₃ of a condenser structure 600 that covers the upper surface of the support substrate 60 may be thinner than the thickness dr of the tape TP. A thickness d₂ of a condenser structure 600 that covers a side surface of the package body 500 may be thinner than each of the thickness d₁ of the condenser structure 600 that covers the upper surface of the package body 500 and the thickness d₃ of the condenser structure 600 that covers the upper surface of the support substrate 60. The thickness d₂ of the condenser structure 600 that covers the side surface of the package body 500 may be about 10 μm or less, for example, about 1 μm to about 10 μm, about 1.5 μm to about 5 μm, or about 2 μm to about 2.5 μm.

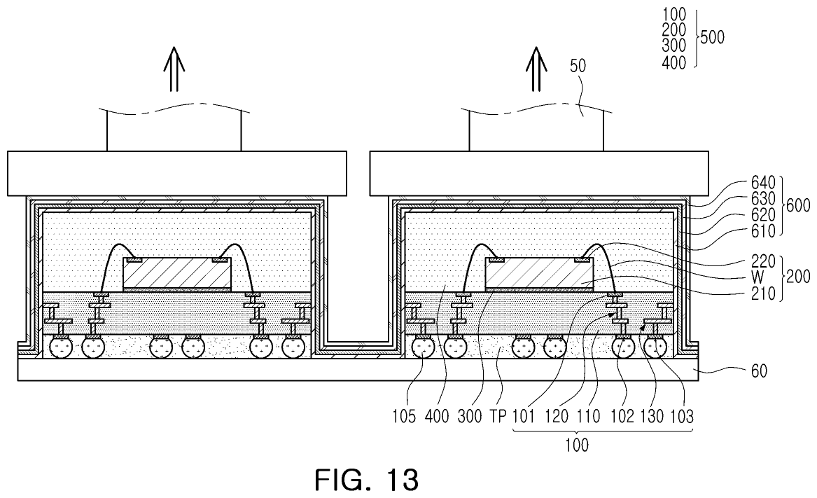

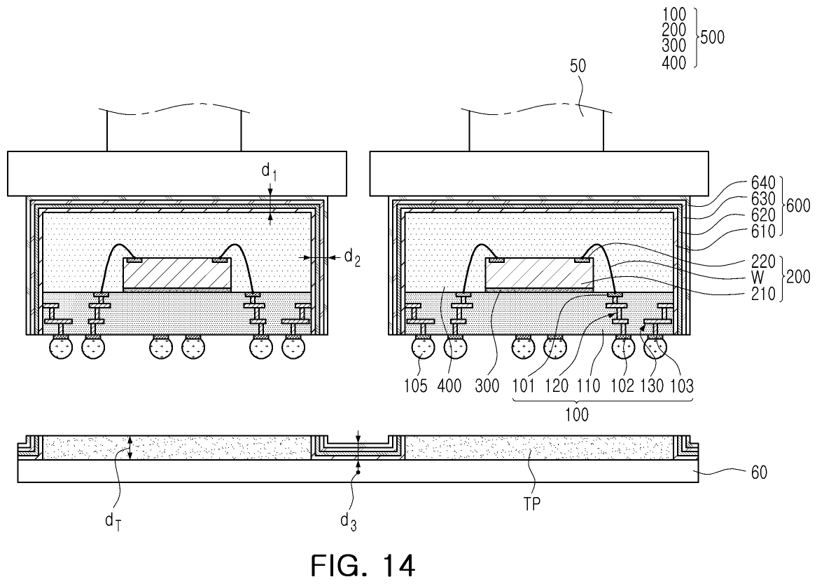

Referring to FIGS. 13 and 14, each of the package substrates 100 of a plurality of package bodies 500 may be vacuum-absorbed by the bonding head 50 and may be separated from the tape TP. Here, the tape TP may be cured by UV irradiation before a plurality of layers 610, 620, 630 and 640 are deposited, and thus, the tape TP may have significantly less adhesive strength to the package substrate 100 (see FIG. 9). In this case, bump structures 105 that are disposed below the package substrate 100 may also be safely separated from the tape TP that is cured together with the package substrate 100.

As the package substrate 100 and the cured tape TP are separated from each other, cracks may propagate to a portion oriented toward the outside of a separated boundary surface, that is, a portion oriented toward the side surface of the condenser structure 600. The condenser structure 600 may be physically separated by the propagation of the cracks, based on the boundary surface where the package substrate 100 and the cured tape TP are separated.

Here, the thickness d₂ of the condenser structure 600 covering the side surface of the package body 500 may be about 10 μm or less, for example, about 1 μm to about 10 μm, about 1.5 μm to about 5 μm, or about 2 μm to about 2.5 μm.

After the condenser structure 600 is physically separated, a lower surface of the condenser structure 600, which covers the side surface of the package body 500, may be substantially coplanar with a lower surface of the package substrate 100.

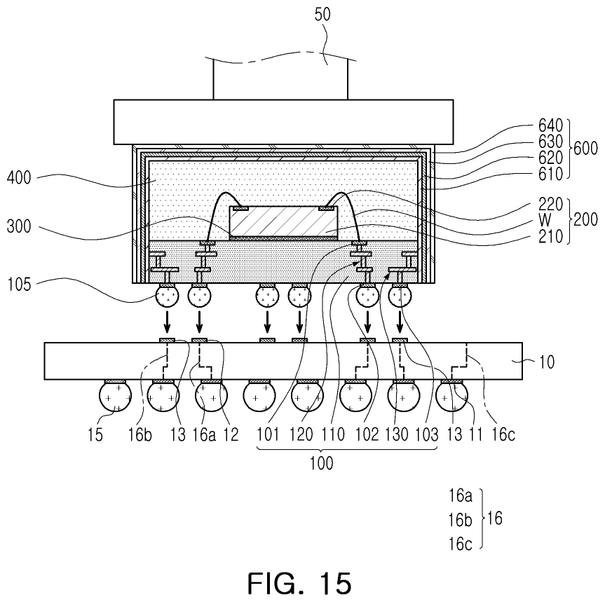

Referring to FIG. 15, a package body 500 that is vacuum-adsorbed by the bonding head 50 may be placed on a previously prepared base substrate 10. Bump structures 105 disposed below the package substrate 100 may be placed on front pads 12 and 13 that are disposed on an upper surface of the base substrate 10.

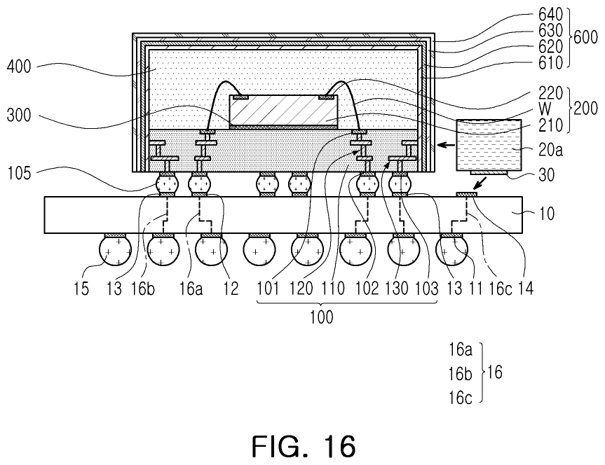

Referring to FIG. 16, a conductive structure 20a may be provided onto a connection pad 14 that is on an upper surface of a base substrate 10. For the conductive structure 20a to be stably attached to the base substrate 10, an adhesive layer 30 at least partially surrounding the connection pad 14 may first be formed before the conductive structure 20a is provided. A side surface of the conductive structure 20a may be provided to come into contact with an external side surface of the condenser structure 600.

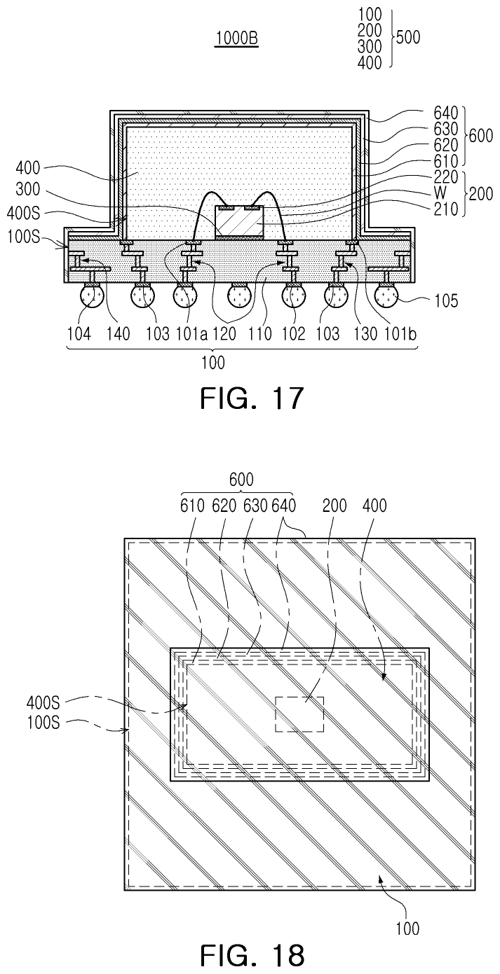

FIG. 17 is a cross-sectional view illustrating a semiconductor package 1000B according to an example embodiment of the present inventive concept. FIG. 18 is a top view of the semiconductor package 1000B of FIG. 17 when viewed from above.

Referring to FIGS. 17 and 18, the semiconductor package 1000B may have characteristics that are identical or similar to those described with reference to FIGS. 1 to 3, except that a first conductive layer 610 does not surround a side surface 100S of a package substrate 100.

Referring to FIGS. 17 and 18, a horizontal area of an encapsulant 400 covering a semiconductor chip 200 may be smaller than a horizontal area of a package substrate 100. For example, the side surface 100S of the package substrate 100 might not be coplanar with a side surface 400S of the encapsulant 400. In other words, the side surface 100S of the package substrate 100 may protrude beyond the side surface 400S of the encapsulant 400.

In addition, the package substrate 100 may include a plurality of wiring layers 120, 130 and 140. Among the plurality of wiring layers, a first wiring layer 120 may be connected to a first upper pad 101a that is connected to a conductive wire W of the semiconductor chip 200, and a second wiring layer 130 may be connected to a second upper pad 101b that is in contact with a first conductive layer 610. Among the plurality of wiring layers, a third wiring layer 140 may be in contact with and electrically connected to at least one layer of a condenser structure 600. The third wiring layer 140 may be connected to a second conductive layer 640 of the condenser structure 600 at a side surface 100S of the package substrate 100. Each of the plurality of wiring layers 120, 130 and 140 may be electrically insulated from each other.

At least one layer of the condenser structure 600 that covers a package body 500 may form a step portion.

The first conductive layer 610 may cover a side surface and an upper surface of an encapsulant 400, and may be connected to at least a portion of upper pads 101 that is exposed to the upper surface of the package substrate 100, in at least a portion of the upper surface of the package substrate 100. The second wiring layer 130 may provide an electrical connection path to the first conductive layer 610 through the second upper pad 101b, and a first voltage V1 may be applied to the first conductive layer 610 through the second wiring layer 130.

A dielectric layer 620 may extend along a surface of the first conductive layer 610 and the remaining portion of the upper surface of the package substrate 100.

The second conductive layer 640 may be disposed on the dielectric layer 620 and may extend along the side surface 100S of the package substrate 100. The second conductive layer 640 may be connected to the third wiring layer 140 of the package substrate 100 at the side surface 100S of the package substrate 100. The third wiring layer 140 may provide an electrical connection path to the second conductive layer 640, and a second voltage V2 may be applied to the second conductive layer 640 through the third wiring layer 140.

The first voltage V1 applied to the first conductive layer 610 may be greater than the second voltage V2 applied to the second conductive layer 640.

The third conductive layer 630 may be disposed between the first conductive layer 610 and the second conductive layer 640. The third conductive layer 630 may cover a surface of the dielectric layer 620. A side end of the third conductive layer 630 disposed on the upper surface of the package substrate 100 may be substantially coplanar or coplanar with a side end of the dielectric layer 620 at an end of the package substrate 100.

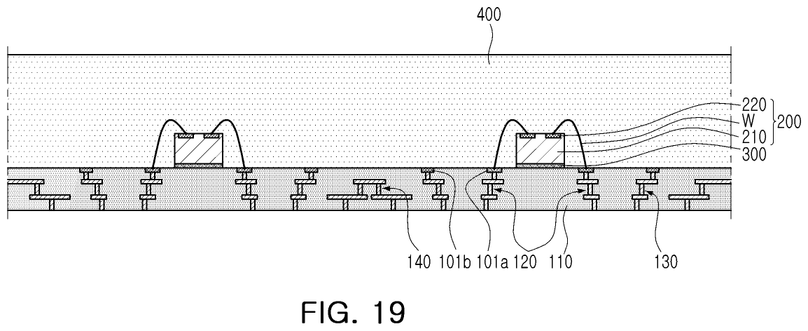

FIGS. 19 to 27 are cross-sectional views schematically illustrating a manufacturing process of a semiconductor package 1000B according to an example embodiment of the present inventive concept.

Referring to FIG. 19, ‘a second package assembly’ may be provided in a face-down form. The second package assembly may include an insulating layer 110 in which a plurality of wiring layers 120, 130 and 140 are disposed and which extends horizontally. A plurality of semiconductor chips 200 attached with an insulating film 300 may be arranged horizontally on one surface of the insulating layer 110, and an encapsulant 400 at least partially surrounding the plurality of semiconductor chips 200 may be disposed on one surface of the insulating layer 110.

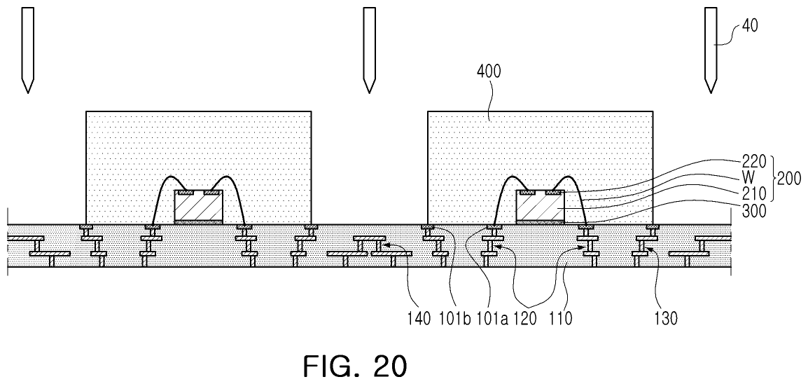

Referring to FIG. 20, a process of sawing up to a level of an upper surface of an insulating layer 110 in a direction, substantially perpendicular to an upper surface of a second package assembly using a cutter 40, is illustrated. A portion of an upper surface of the package substrate 100 may be exposed by means of the sawing process.

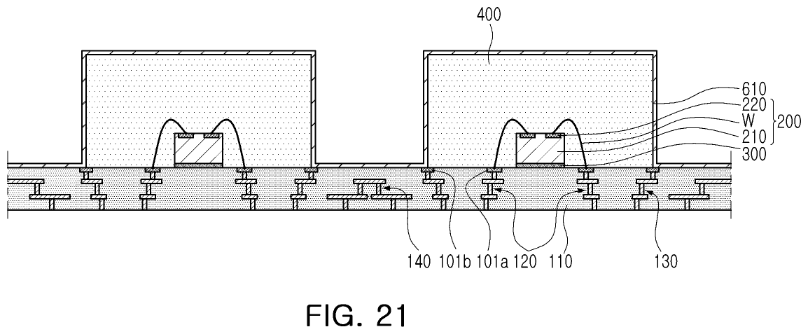

Referring to FIG. 21, a first conductive layer 610 may be deposited on an upper surface and a side surface of the encapsulant 400 and the exposed upper surface of the package substrate 100. The deposition may be performed by a sputtering process, but the present inventive concept is not limited thereto.

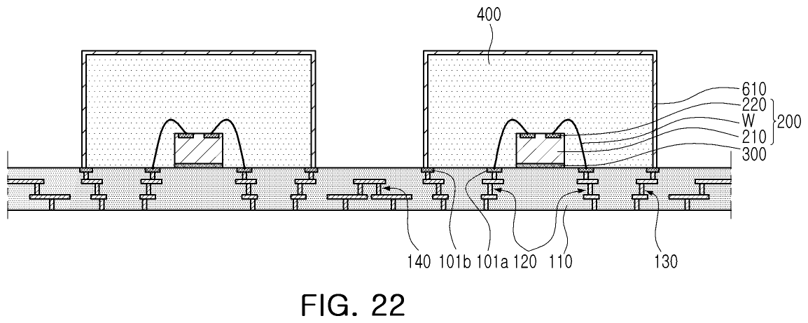

Referring to FIG. 22, a first conductive layer 610 that is deposited on the exposed upper surface of the package substrate 100 may be removed by the cutter 40.

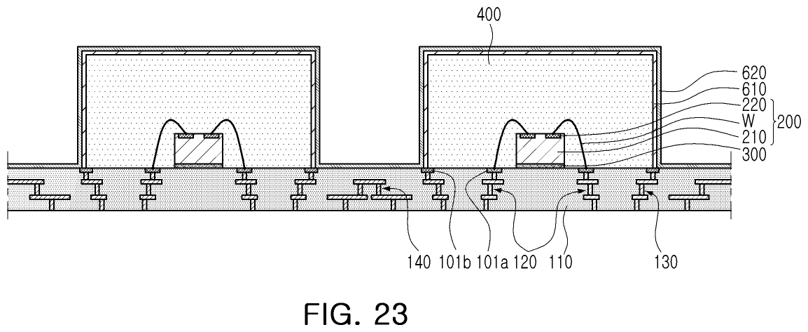

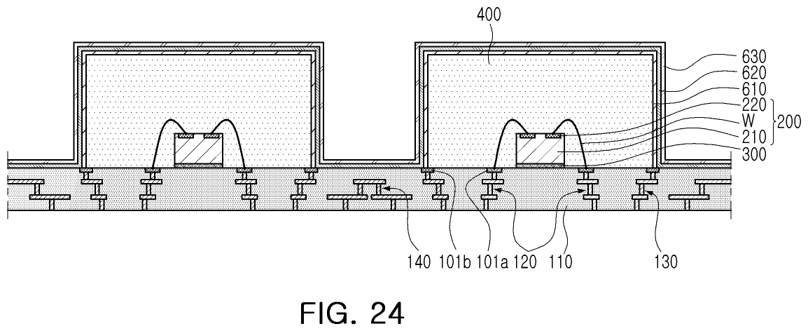

Referring to FIG. 23, a dielectric layer 620 may be deposited on a surface of the first conductive layer 610 and the exposed upper surface of the package substrate 100, and referring to FIG. 24, a third conductive layer 630 may be deposited on a surface of the dielectric layer 620.

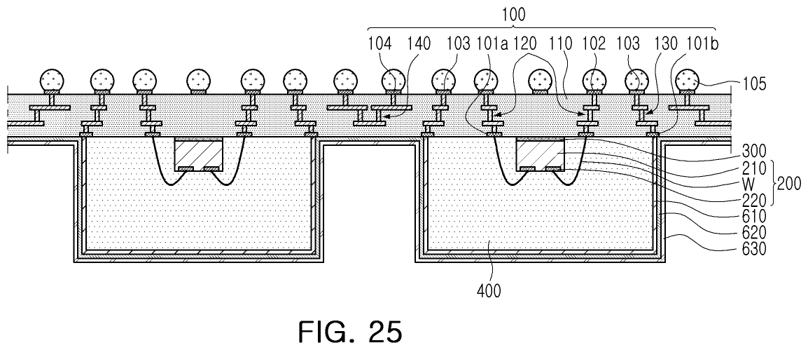

Referring to FIG. 25, a package body 500 in which a plurality of layers 610, 620 and 630 are deposited may be provided to be face-up, and bump structures 105 may be attached to the lower pads 102, 103 and 104 that are disposed on a lower surface of the package substrate 100.

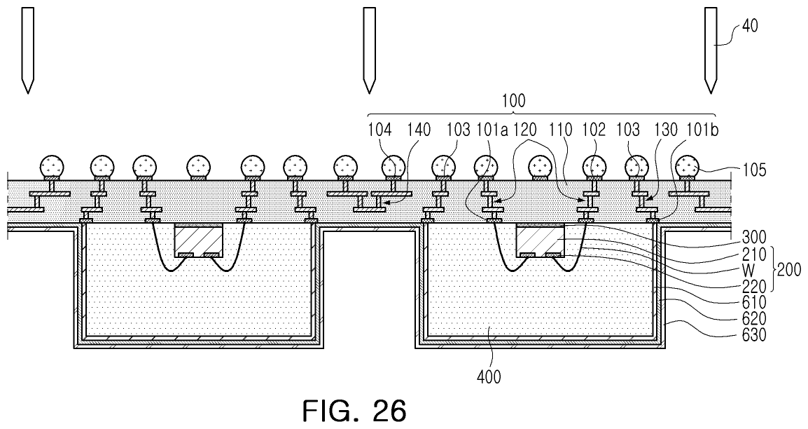

Referring to FIG. 26, a back-side of the package substrate 100 may be cut in a vertical direction using the cutter 40, and may be separated into a plurality of package bodies 500.

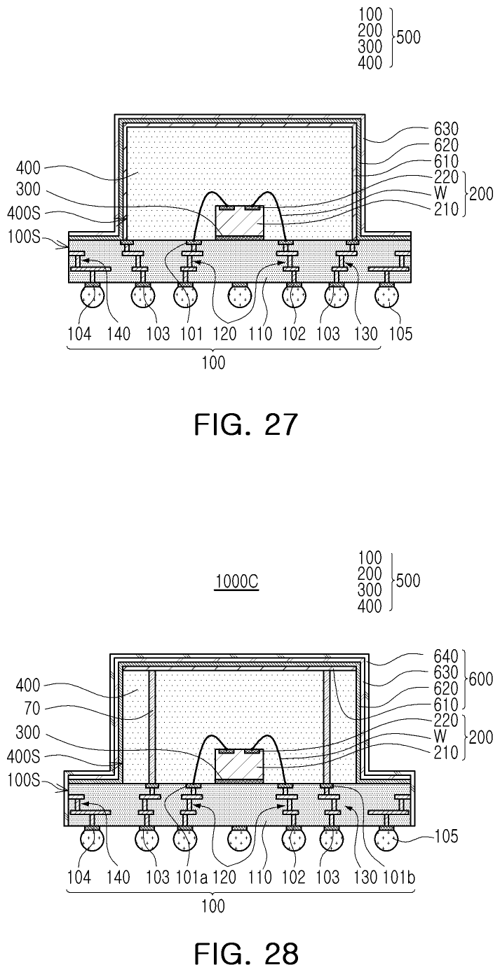

Referring to FIG. 27, one package body 500 among a plurality of package bodies 500 is illustrated. Finally, a second conductive layer 640 may be deposited on a surface of the third conductive layer 630 and a side surface 100S of the package substrate.

FIG. 28 is a cross-sectional view illustrating a semiconductor package 1000C according to an example embodiment of the present inventive concept.

Referring to FIG. 28, the semiconductor package 1000C may have characteristics that are identical or similar to those described with reference to FIGS. 17 and 18, except that the connection structure 70 is disposed inside the encapsulant 400.

A first conductive layer 610 may be disposed to cover an upper surface of the encapsulant 400. The connection structure 70 may be disposed inside the encapsulant 400 for electrically connecting the first conductive layer 610 and a second upper pad 101b to each other. The connection structure 70 may include a conductive material. The connection structure 70 may include a metal including, for example, tin (Sn), iron (Fe), nickel (Ni), or alloys thereof, but the present inventive concept is not limited thereto. The connection structure 70 may be a pillar-shaped structure, but the present inventive concept is not limited thereto. For example, the connection structure 70 may have a cylindrical shape. For example, the connection structure 70 may be in the form of a wire. In this case, a wire ball for connecting a wire body and the second upper pad 101b to each other may be disposed in a lower portion of the connection structure 70. The connection structure 70 may be arranged to extend in a direction, substantially perpendicular to an upper surface of the package substrate 100 within the encapsulant 400, but the present inventive concept is not limited thereto. For example, when the connection structure 70 has a wire shape, the connection structure 70 may extend in a direction of forming an arbitrary angle (greater than 0° and less than 90°) with the upper surface of the package substrate 100 to be connected to the first conductive layer 610. A second wiring layer 130 may provide an electrical connection path to the first conductive layer 610 through the second upper pad 101b and the connection structure 70, and a first voltage V1 may be applied to the first conductive layer 610 through the second wiring layer 130.

A dielectric layer 620 may be disposed to cover an upper surface and a side surface of the first conductive layer 610 and a side surface 400S of the encapsulant.

The second conductive layer 640 may be disposed on the dielectric layer 620 and may extend along the side surface 100S of the package substrate 100. The second conductive layer 640 may be connected to a third wiring layer 140 of the package substrate 100 on the side surface 100S of the package substrate 100. The third wiring layer 140 may provide an electrical connection path to the second conductive layer 640, and a second voltage V2 may be applied to the second conductive layer 640 through the third wiring layer 140.

The first voltage V1 applied to the first conductive layer 610 may be greater than the second voltage V2 applied to the second conductive layer 640.

The third conductive layer 630 may be disposed between the first conductive layer 610 and the second conductive layer 640. The third conductive layer 630 may cover a surface of the dielectric layer 620. A side end of the third conductive layer 630 disposed on the upper surface of the package substrate 100 may be substantially coplanar or coplanar with a side end of the dielectric layer 620 and an end of the package substrate 100.

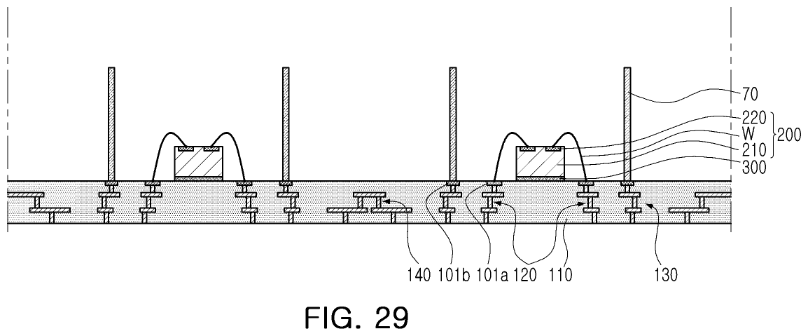

FIGS. 29 to 38 are cross-sectional views schematically illustrating the manufacturing process of the semiconductor package 1000C according to an example embodiment of the present inventive concept.

Referring to FIG. 29, a plurality of semiconductor chips 200, which are attached to at least a portion of an upper surface of a horizontally extending insulating layer 110 with an adhesive film 300, may be provided. Referring to FIG. 29, the connection structure 70 may be formed to be connected to some of the upper pads 101 that are exposed on the top surface of the package substrate 100. A connection structure 70 may be a pillar-shaped structure. In this case, the connection structure 70 may be formed to extend in a direction, substantially perpendicular to an upper surface of a package substrate 100. The connection structure 70 may also be formed in the form of a wire. In this case, a wire ball may be formed on a lower portion of the connection structure 70, and a wire body may be formed to extend from the wire ball. For example, the wire ball may be formed on the second upper pad 101b. In this case, the wire body may be formed to form an arbitrary angle (greater than 0° but less than 90°) with the upper surface of the package substrate 100.

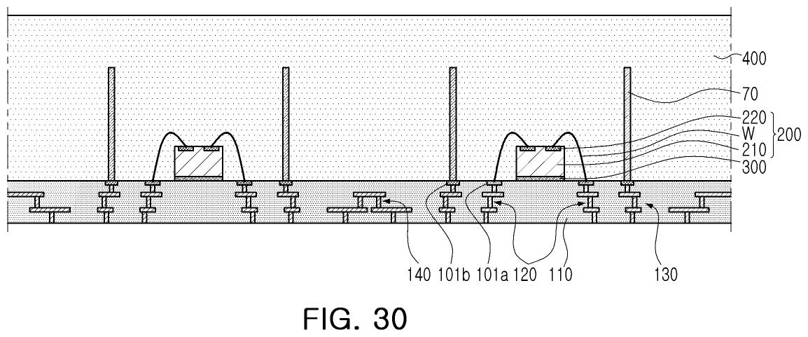

Referring to FIG. 30, an encapsulant 400 may surround and seal a semiconductor chip 200 and the connection structure 70 on the package substrate 100.

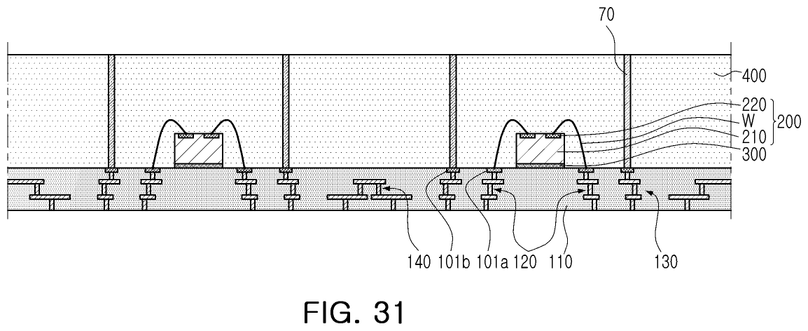

Referring to FIG. 31, an upper surface of the encapsulant 400 may be planarized to be coplanar with an upper surface of the connection structure 70. A planarization process may be performed, for example, through a chemical mechanical polishing (CMP) process.

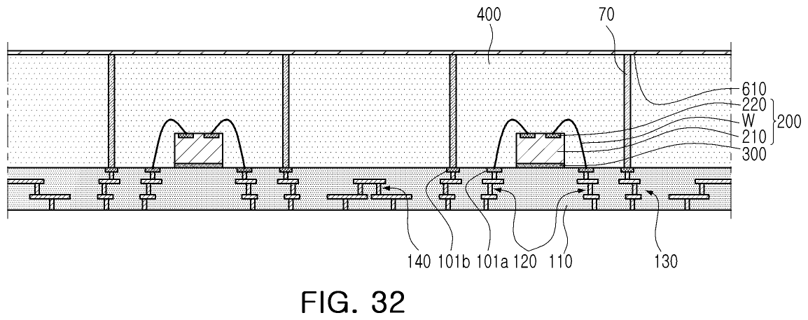

Referring to FIG. 32, a first conductive layer 610 may be deposited on an upper surface of the encapsulant 400 and the upper surface of the connection structure 40.

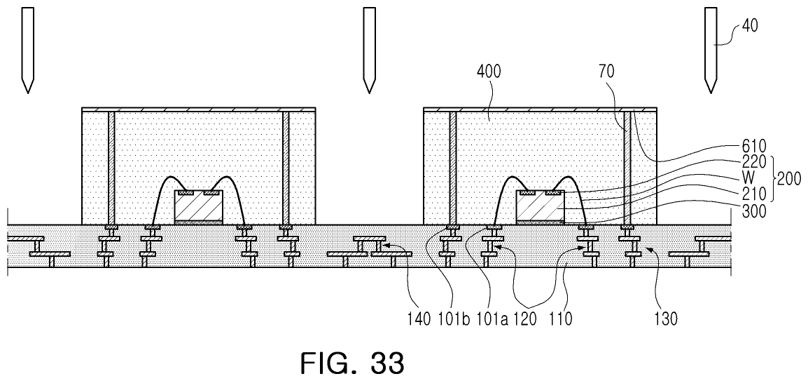

Referring to FIG. 33, a cutter 40 may be used to cut up to a level of an upper surface of the package substrate 100 in a direction, perpendicular to an upper surface of an insulating layer 110. A side surface 400S of the encapsulant and a portion of the upper surface of the package substrate 101 may be exposed.

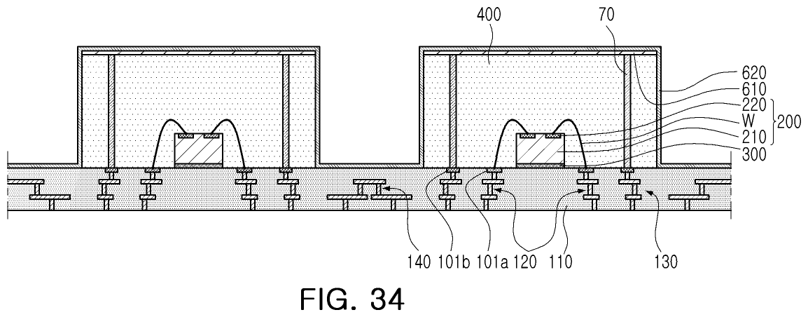

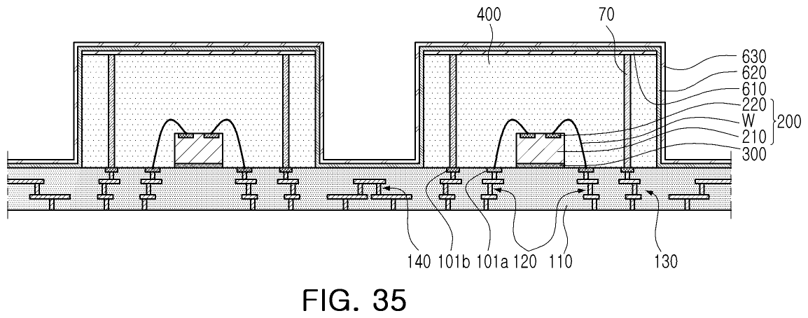

Referring to FIG. 34, a dielectric layer 620 may be deposited on a surface of the first conductive layer 610, a side surface 400S of the encapsulant, and the exposed upper surface of the package substrate 100. Referring to FIG. 35, a third conductive layer 630 may be deposited on a surface of the dielectric layer 620.

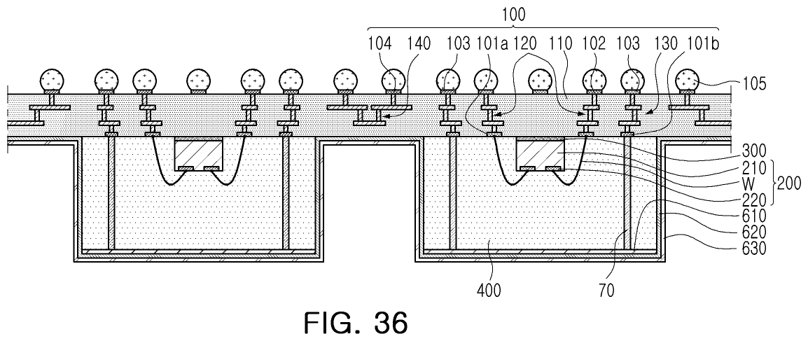

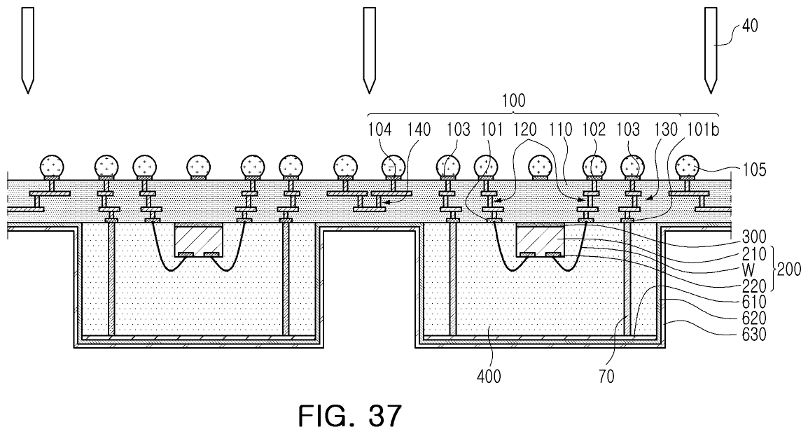

Referring to FIG. 36, a structure in which a plurality of layers 610, 620 and 630 are deposited on a side surface and an upper surface of an encapsulant 400 and an upper surface of a package substrate 100 may be provided to be face-up, and referring to FIG. 37, a back-side of the structure may be cut in a vertical direction by using a cutter 40 and may be separated into a plurality of package bodies 500.

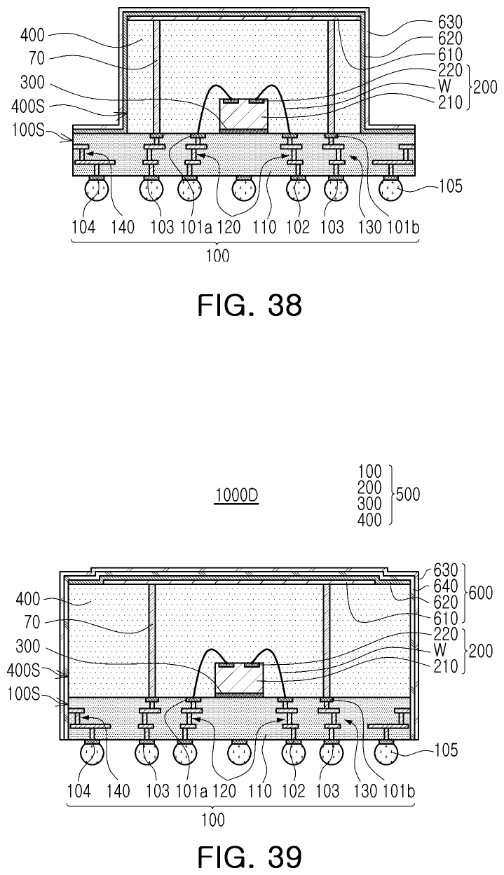

Referring to FIG. 38, one package body 500 among a plurality of package bodies 500 is illustrated. Finally, a second conductive layer 640 may be deposited on a surface of the third conductive layer 630 and a side surface 100S of the package substrate.

FIG. 39 is a cross-sectional view illustrating a semiconductor package 1000D according to an example embodiment of the present inventive concept.

Referring to FIG. 39, the semiconductor package 1000D may have characteristics that are identical or similar to those described with reference to FIG. 28, except that a side surface 400S of an encapsulant and a side surface 100S of a package substrate 100 are substantially coplanar with each other, and a third conductive layer 630 is disposed outside a second conductive layer 640.

A first conductive layer 610 may be disposed to cover at least a portion of an upper surface of the encapsulant 400. A side surface of the first conductive layer 610 may have a step portion from the side surface 400S of the encapsulant 400. A connection structure 70 for electrically connecting the first conductive layer 610 and a second upper pad 101b may be disposed inside the encapsulant 400. The connection structure 70 may have characteristics identical or similar to those described with reference to FIG. 28. A second wiring layer 130 may provide an electrical connection path to the first conductive layer 610 through the second upper pad 101b and the connection structure 70, and a first voltage V1 may be applied to the first conductive layer 610 through the second wiring layer 130.

The dielectric layer 620 may be disposed to cover at least a surface of the first conductive layer 610 and a portion of an upper surface of the encapsulant 400. An upper surface of the dielectric layer 620 may have a step portion. For example, a level of an upper surface of a portion of the dielectric layer 620 covering an upper surface of the first conductive layer 610 may be higher than a level of an upper surface of a portion of the dielectric layer 620 covering at least a portion of an upper surface of the encapsulant 400. A side surface of the dielectric layer 620 may be substantially coplanar or coplanar with a side surface 400S of the encapsulant 400.

A second conductive layer 640 may cover a surface of the dielectric layer 620 and may extend along the encapsulant 400 and a side surface 100S of the package substrate 100.

An upper surface of the second conductive layer 640 that is disposed on the encapsulant 400 may have a step portion. For example, a level of an upper surface of a portion of the second conductive layer 640 that is disposed on the first conductive layer 610 may be higher than a level of an upper surface of at least a portion of the second conductive layer 640 that is disposed on the encapsulant 400. In the present example embodiment, the second conductive layer 640 may be connected to a third wiring layer 140 on the side surface 100S of the package substrate 100. The third wiring layer 140 may provide an electrical connection path to the second conductive layer 640, and a second voltage V2 may be applied to the second conductive layer 640 through the third wiring layer 140.

The first voltage V1 applied to the first conductive layer 610 may be greater than the second voltage V2 applied to the second conductive layer 640.

The third conductive layer 630 may be disposed on the second conductive layer 640. An upper surface of the third conductive layer 630 that is disposed on the encapsulant 400 may have a step portion. For example, a level of an upper surface of a portion of the third conductive layer 630 that is disposed on the first conductive layer 610 may be higher than a level of an upper surface of at least a portion of the third conductive layer 630 that is disposed on the encapsulant 400.

In the present example embodiment of the present inventive concept, the third conductive layer 630 may be a layer for preventing the semiconductor package 1000D from being subject to electromagnetic interference (EMI) from the outside. In this case, a layer for preventing the third conductive layer 630 from being oxidized may be additionally stacked on a surface of the third conductive layer 630. The layer additionally stacked on the surface of the third conductive layer 630 may have electrical conductivity lower than that of the third conductive layer 630. The electrical conductivity of the third conductive layer 630 may be greater than the electrical conductivity of the first conductive layer 610 and the second conductive layer 640. The first conductive layer 610, the second conductive layer 640, and the third conductive layer 630 may include the materials identical or similar to those of the first conductive layer 610, the second conductive layer 640, and the third conductive layer 630 described with reference to FIGS. 1 and 2, respectively.

In addition, in the present example embodiment of the present inventive concept, the second conductive layer 640 may be a layer for preventing the semiconductor package 1000D from being subject to electromagnetic interference (EMI) from the outside, and the third conductive layer 630 may be a layer for preventing the second conductive layer 640 from being oxidized. In this case, the electrical conductivity of the second conductive layer 640 may be greater than the electrical conductivity of the first conductive layer 610 and the third conductive layer 630.

The plurality of conductive layers 610, 630 and 640 may include a conductive material. For example, the first conductive layer 610 may include a metal including at least one of tin (Sn), iron (Fe), nickel (Ni), or alloys thereof, but the present inventive concept is not limited thereto. For example, the first conductive layer 610 may include steel used stainless (SUS). The third conductive layer 630 may include a material similar to the first conductive layer 610. However, the materials of the first conductive layer 610 and the third conductive layer 630 are not limited to the materials described above. The second conductive layer 640 may include a metal including, for example, gold (Au), silver (Ag), copper (Cu), or alloys thereof, but the present inventive concept is not limited thereto.

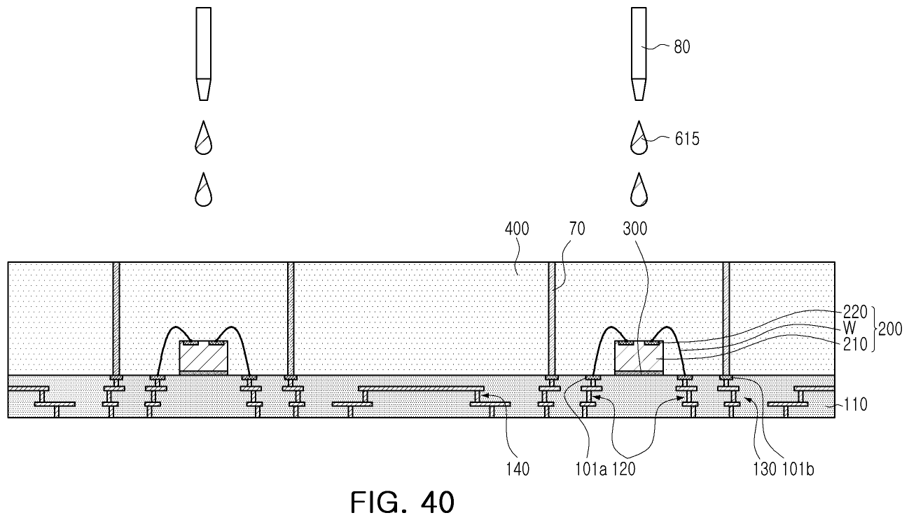

FIGS. 40 to 47 are cross-sectional views schematically illustrating the manufacturing process of a semiconductor package 1000D according to an example embodiment of the present inventive concept.

Referring to FIG. 40, ‘a third package assembly’ may be provided in a face-down form, in a manner identical or similar to those described with reference to FIGS. 29, 30, and 31. A fourth package assembly be provided to include a plurality of semiconductor chips 200, which are attached with an adhesive film 300 to at least a portion of an upper surface of an insulating layer 110 extending horizontally, a connection structure 70, which is connected to a portion of upper pads 101 that are exposed onto an upper surface of a package substrate 100, and an encapsulant 400 at least partially surrounding the semiconductor chip 200 and the connection structure 70 on the package substrate 100

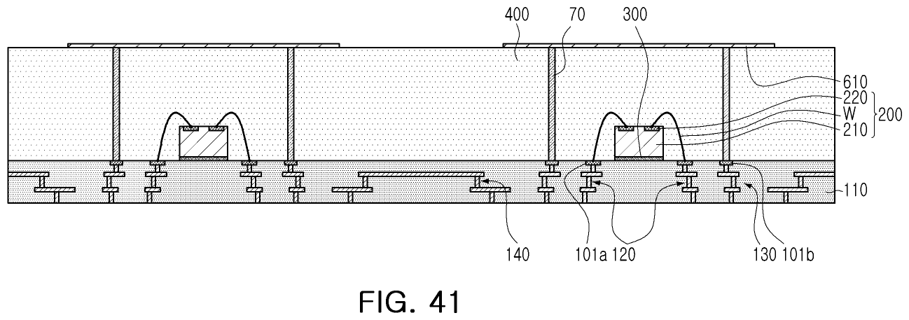

Referring to FIGS. 40 and 41, a first conductive layer 610 may be disposed on a portion of an upper surface of the encapsulant 400 in an inkjet printing manner. For example, the first conductive layer 610 may be coated on the connection structure 70 in which an upper surface thereof is exposed. The inkjet printing manner may comply with a conventional method. For example, a liquid composition 615 constituting a first conductive layer may be discharged from an inkjet head 80 which includes a nozzle, and the first conductive layer 610 is disposed on a portion of the upper surface of the encapsulant 400.

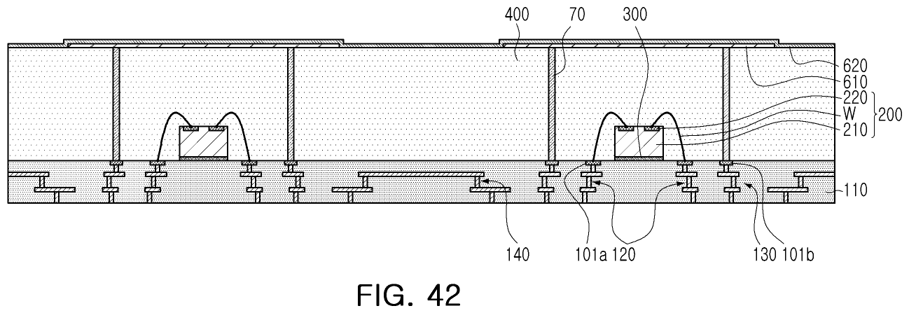

Referring to FIG. 42, a dielectric layer 620 may be deposited to cover a surface of the first conductive layer 610 and at least a portion of the upper surface of the encapsulant 400. Here, the deposition may include physical vapor deposition (PVD), chemical vapor deposition (CVD), and atomic layer deposition (ALD), but the present inventive concept is not limited thereto. The deposition may be performed by a sputtering process even in physical vapor deposition (PVD), but the present inventive concept is not limited thereto.

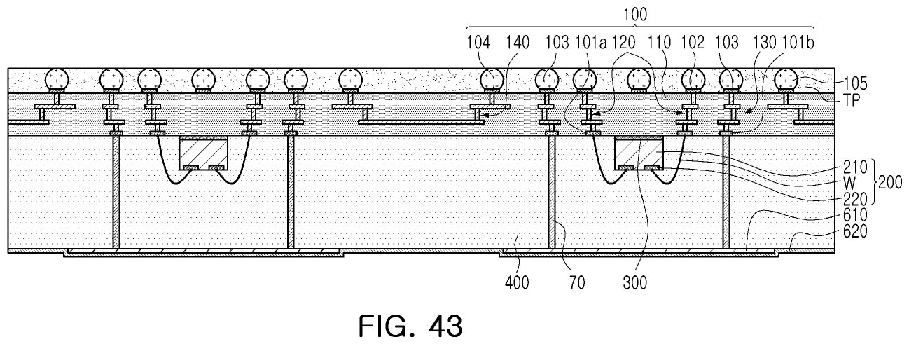

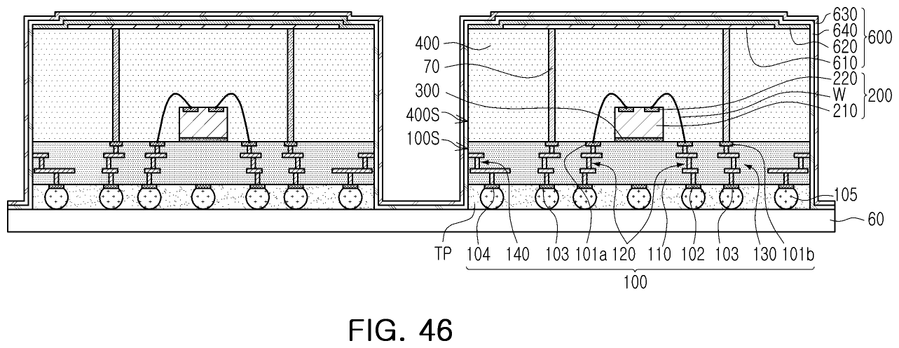

Referring to FIG. 43, a structure in which the first conductor layer 610 and the dielectric layer 620 are formed on the encapsulant 400 may be provided to be face-up. Lower pads 102, 103 and 104 may be disposed on a lower surface of the package substrate 100 of the structure, and bump structures 105 may be attached to the lower pads 102, 103 and 104. Furthermore, for the deposition process according to FIG. 46, a tape TP may be attached to cover one side surface of the package substrate 100 and to at least partially surround a plurality of connection bumps 105.

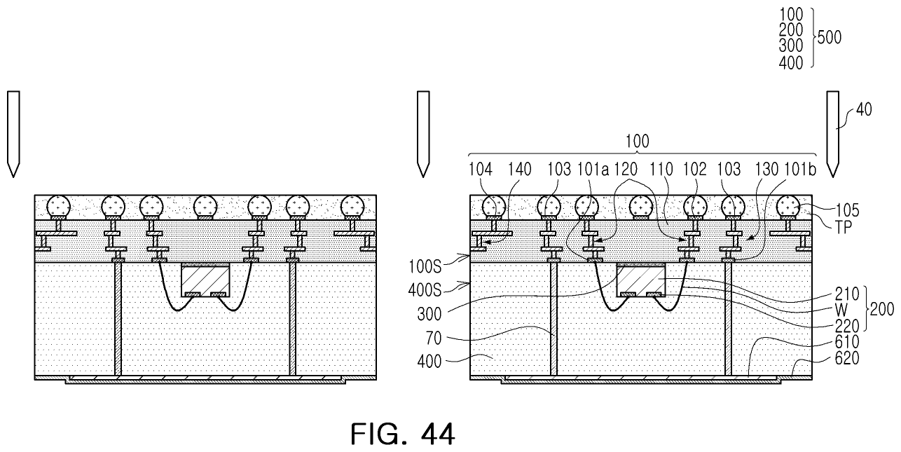

Referring to FIG. 44, a cutter 40 may be used to saw in a direction, substantially perpendicular to an upper surface of the tape TP. Through the sawing process, a plurality of package bodies 500 may be provided, and a portion of a wiring layer 140 of the package substrate 100 may be exposed at a side surface 100S of the package substrate 100.

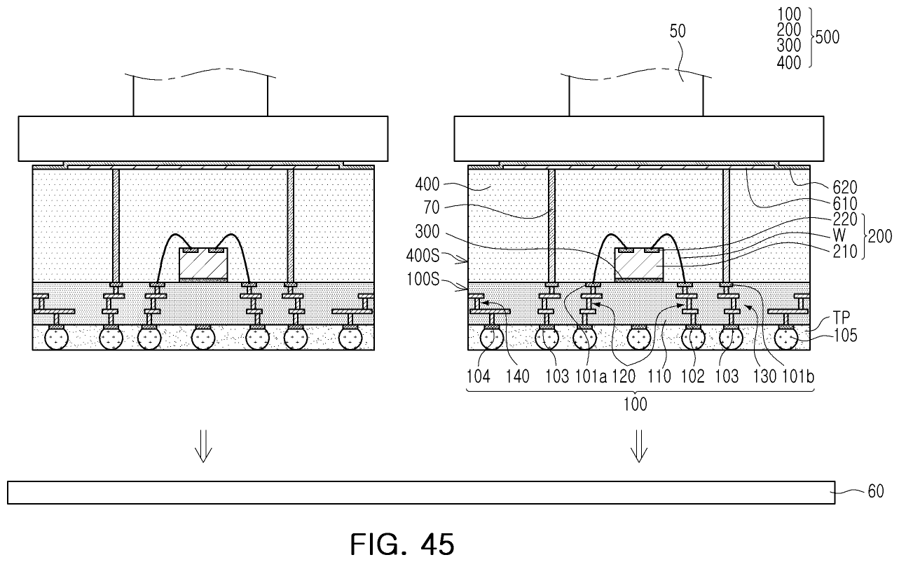

Referring to FIG. 45, each of the plurality of package bodies 500 may be picked-up with vacuum adsorption force from a bonding head 50 and may be placed on a support substrate 60. The support substrate 60 may have the feature identical or similar to those described with reference to FIG. 6.

Referring to FIG. 46, a second conductive layer 640 may be deposited to cover a surface of a dielectric layer 620, a side surface 400S of an encapsulant 400, a side surface 100S of a package substrate 100, a side surface of a tape TP, and an upper surface of a support substrate 60. A third conductive layer 630 may be deposited to cover a surface of the second conductive layer 640. A structure in which a first conductive layer 610, the dielectric layer 620, the second conductive layer 640, and the third conductive layer 630 are sequentially stacked may be formed. The deposition may be performed in the manner identical or similar to those described in FIG. 42.

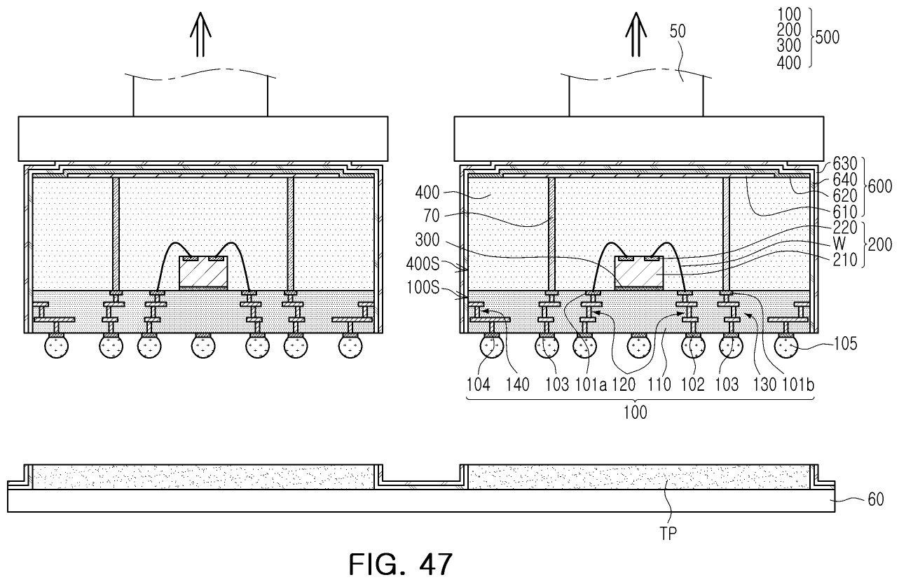

Referring to FIG. 47, each of package substrates 100 of a plurality of package bodies 500 may be vacuum-adsorbed to a bonding head 50 and may be separated from the tape TP in the manner identical or similar to those described in FIGS. 13 and 14.

While the present inventive concept has been described with reference to embodiments thereof, it will be understood by those of ordinary skill in the art that various changes in form and details may be made thereto without departing from the spirit and scope of the present inventive concept.

What is claimed is:

1. A semiconductor package comprising:
a package substrate including upper pads, lower pads, and a first wiring layer electrically connecting first upper pads of the upper pads to first lower pads of the lower pads, respectively;
a semiconductor chip disposed on the package substrate and electrically connected to the first upper pads;
an encapsulant covering the semiconductor chip and at least a portion of the package substrate;
a first conductive layer covering at least a portion of each of the encapsulant and the package substrate, wherein the first conductive layer is configured to be applied a first voltage;
a dielectric layer stacked on the first conductive layer; and
a second conductive layer stacked on the dielectric layer, wherein the second conductive layer is configured to be applied a second voltage.

2. The semiconductor package of claim 1, wherein the first conductive layer, the dielectric layer, and the second conductive layer extend along an upper surface and a side surface of the encapsulant, and a side surface of the package substrate.

3. The semiconductor package of claim 1, wherein the package substrate further comprises a second wiring layer electrically connecting the first conductive layer and second lower pads of the lower pads to each other.

4. The semiconductor package of claim 3, wherein the first conductive layer is in contact with the second wiring layer at a side surface of the package substrate.

5. The semiconductor package of claim 1, wherein the semiconductor package comprises:
a conductive structure in contact with a side surface of the second conductive layer;
a base substrate disposed below the package substrate and the conductive structure; and
a plurality of connection bumps disposed below the base substrate.

6. The semiconductor package of claim 5, wherein the base substrate comprises connection wirings electrically connecting each of the lower pads and the conductive structure to the plurality of connection bumps.

7. The semiconductor package of claim 1, wherein the package substrate further comprises a second wiring layer electrically connecting the first conductive layer and second lower pads of the lower pads to each other, and
the first conductive layer is in contact with the second wiring layer on an upper surface of the package substrate.

8. The semiconductor package of claim 7, wherein the second conductive layer extends along an upper surface of the package substrate and a side surface of the package substrate.

9. The semiconductor package of claim 8, wherein the package substrate further includes a third wiring layer electrically connecting the second conductive layer and third lower pads of the lower pads to each other, and
the second conductive layer is in contact with the third wiring layer at the side surface of the package substrate.

10. The semiconductor package of claim 1, wherein the first voltage is greater than the second voltage.

11. The semiconductor package of claim 6, wherein the base substrate includes a connection pad disposed between the conductive structure and one of the connection wirings that electrically connects the conductive structure to at least one of the plurality of connection bumps, and an adhesive layer at least partially surrounding the connection pad.

12. The semiconductor package of claim 1, further comprising:
a third conductive layer between the first conductive layer and the second conductive layer,
wherein electrical conductivity of the third conductive layer is greater than each of electrical conductivity of the first conductive layer and electrical conductivity of the second conductive layer.

13. The semiconductor package of claim 1, wherein a thickness of the dielectric layer is greater than a thickness of at least one of the first conductive layer or the second conductive layer.

14. The semiconductor package of claim 13, wherein the thickness of each of the first and second conductive layers is about 0.5 μm or less, and
the thickness of the dielectric layer is about 5 μm or less.

15. A semiconductor package comprising:
a package body including a package substrate, which includes a first wiring layer and a second wiring layer, a semiconductor chip, which is disposed on the package substrate and is electrically connected to the first wiring layer, and an encapsulant covering the semiconductor chip and at least a portion of the package substrate;
a condenser structure including a first conductive layer, which is covers a side surface and an upper surface of the package body, a dielectric layer, which is disposed on the first conductive layer, and a second conductive layer, which is disposed on the dielectric layer;
a conductive structure contacting with the second conductive layer of the condenser structure;
a base substrate including first connection wiring, which is disposed below the package body and the conductive structure and is electrically connected to the first wiring layer, a second connection wiring electrically connected to the second wiring layer, and a third connection wiring electrically connected to the conductive structure; and
first to third connection bumps disposed below the base substrate and electrically connected to the first to third connection wirings, respectively.

16. The semiconductor package of claim 15, wherein a first voltage is applied to the first conductive layer through the second connection bump, the second connection wiring, and the second wiring layer, and
a second voltage, which is lower than the first voltage, is applied to the second conductive layer through the third connection bump and the third connection wiring.

17. The semiconductor package of claim 15, wherein the dielectric layer includes at least one of ZrO₂ or HfO₂.

18. The semiconductor package of claim 15, further comprising:
a third conductive layer disposed between the dielectric layer and the second conductive layer,
wherein the third conductive layer includes a metal different from that of each of the first conductive layer and the second conductive layer.

19. The semiconductor package of claim 18, wherein the third conductive layer includes copper (Cu).

20. A semiconductor package comprising:
a package substrate including first and second upper pads, first, second and third lower pads, a first wiring layer, which electrically connects the first upper pads to the first lower pads, a second wiring layer, which electrically connects the second upper pads to the second lower pads, and a third wiring layer, which is electrically connected to the third lower pads;
a semiconductor chip disposed on the package substrate and electrically connected to the first upper pads;
an encapsulant covering the semiconductor chip and a first portion of an upper surface of the package substrate;
a first conductive layer covering a side surface and an upper surface of the encapsulant, wherein the first conductive layer is connected to the second upper pads that are disposed in a second portion of the upper surface of the package substrate;
a dielectric layer extending along a surface of the first conductive layer and the second portion of the upper surface of the package substrate; and
a second conductive layer extending along a surface of the dielectric layer and a side surface of the package substrate, wherein the second conductive layer is connected to the third wiring layer at the side surface of the package substrate.
